(19) United States
(12) Patent Application Publication
(10) Pub. No.: US 2025/0021711 A1
(43) Pub. Date: Jan. 16, 2025

(54) System and Method of Imaging a Construction Plan onto a Walkable Area

(71) Applicant: Awan Capital Partners IP, L.L.C, Dallas, TX (US)

(72) Inventor: Daniyal Mushtaq Awan, Dallas, TX (US)

(21) Appl. No.: 18/902,558

(22) Filed: Sep. 30, 2024

Related U.S. Application Data
(63) Continuation-in-part of application No. 18/325,789, filed on May 30, 2023, now abandoned.
Application No. 18/325,789 is a continuation of application No. 17/098,244, filed on Nov. 13, 2020, now abandoned.
(60) Provisional application No. 62/934,658, filed on Nov. 13, 2019.

(51) Int. Cl. G06F 30/13; G03B 21/28; G06F 3/01; G06T 17/05

(52) U.S. Cl. CPC G06F 30/13; G03B 21/28; G06F 3/011; G06T 17/05

(57) ABSTRACT

A system and method is provided for imaging a construction plan onto a walkable area. The system includes a plurality of light-emitting diode (LED) cabinets, a video processing unit, and a personal computing (PC) device. The plurality of LED cabinets are walkable ground displays capable of outputting an image. The video processing unit manages the plurality of LED cabinets in order for a single image of a desired construction plan to be outputted. The PC device allows for user input to manage and control what is outputted by the plurality of LED cabinets. The desired construction plan can be selected with the PC device. The video processing unit partitions the desired construction plan and assigns a plurality of plan portions to a corresponding LED cabinet. The corresponding LED cabinet then outputs a single image of the desired construction plan onto a walkable area.

The current application is a continuation-in-part (CIP) application of the U.S. non-provisional patent application Ser. No. 18/325,789 filed on May 30, 2023. The U.S. non-provisional patent application Ser. No. 18/325,789 is a continuation application of the U.S. non-provisional patent application Ser. No. 17/098,244 filed on Nov. 13, 2020. The U.S. non-provisional patent application Ser. No. 17/098,244 claims a priority to the U.S. provisional patent application Ser. No. 62/934,658 filed on Nov. 13, 2019.

### FIELD OF THE INVENTION

The present invention relates generally to virtual construction plans and display systems. More specifically, the present invention discloses novel means of displaying a construction plan onto a walkable area.

### BACKGROUND OF THE INVENTION

In general, most real-estate developers often need to be able to walk through a future project's construction plan before the project is built. Once the project is completed, making changes and alterations to the project is expensive and time consuming. So, being able to monitor and make changes to the construction plan in early stages of construction is beneficial. The present invention enables users to experience and visualize the construction space before the project is built. By facilitating the visualization of the construction plan, users can determine if changes or alterations need to be made at early stages of the project. Thus, project costs are kept low, and users can ensure that the construction meets all required specifications. New homeowners, architects, designers, or other similar users can use the present invention to walk through the actual designs displayed on a 1:1 scale and make changes in the plans before finishing the construction projects.

Some existing solutions are available that help users visualize construction plans. For example, virtual 3-D tours and similar modelling methods to view construction plans on a 1:1 scale are available. However, these existing solutions are expensive and time consuming so not every developer or home builder can afford them. Moreover, these current methods require special high-performance software, hardware, and a skilled designer to make them. On the other hand, the present invention provides a more cost-effective and practical solution that requires less space, cheaper equipment, is less technical to setup, is more reliable, and is essentially a better and more intuitive experience for a client. The present invention uses the actual construction plan that is submitted to the city for permits, so the construction plan is already required for construction and no additional time or money is spent to create design files for the present invention to display. Moreover, the present invention also outputs an actual 1:1 scale walkable tour the user can experience, hence the present invention allows maximum feel of the future construction spaces and dimensions. Additional features and benefits of the present invention are further discussed in the sections below.

### BRIEF DESCRIPTION OF THE DRAWINGS

FIG. 1 is a top-front-left perspective view of a first embodiment of the Light Emitting Diode (LED) cabinet of the system of the present invention.

FIG. 2 is a bottom-front-right perspective view of the first embodiment of the LED cabinet of the system of the present invention.

FIG. 3 is a bottom-front-right perspective view of a second embodiment of the LED cabinet of the system of the present invention.

FIG. 4 is a top view of the LED cabinet of the system of the present invention.

FIG. 5 is a top-front-left perspective view of a display assembly formed with several LED cabinets of the system of the present invention.

FIG. 6 is a bottom-rear-right perspective view of the display assembly formed with several LED cabinets of the system of the present invention.

FIG. 7 is a top view of the display assembly formed with several LED cabinets of the system of the present invention, wherein a desired construction plan is displayed as a single image on the display assembly.

FIG. 8 is a schematic view of the overall system of the present invention.

FIG. 9 is a flowchart illustrating the overall process of the method of the present invention.

FIG. 10 is a flowchart illustrating the continuation of the overall process of the method of the present invention.

FIG. 11 is a flowchart illustrating the subprocess of mounting the display assembly on several leveling trusses of the present invention.

FIG. 12 is a flowchart illustrating the subprocess of automating the leveling of the display assembly using leveling sensors of the present invention.

FIG. 13 is a flowchart illustrating the subprocess of displaying the desired construction plan as a single image on a 1:1 scale on the display assembly of the present invention.

FIG. 14 is a flowchart illustrating the subprocess of scaling the single image displayed on the display assembly of the present invention.

FIG. 15 is a flowchart illustrating the subprocess of panning the single image displayed on the display assembly of the present invention.

FIG. 16 is a flowchart illustrating the subprocess of adding physical mockup objects on the single image displayed on the display assembly of the present invention.

FIG. 17 is a flowchart illustrating the subprocess of adding plan overlays on the single image displayed on the display assembly of the present invention.

FIG. 18 is a flowchart illustrating the subprocess of editing the single image displayed on the display assembly of the present invention.

FIG. 19 is a flowchart illustrating the subprocess of selecting the desired construction plan to be displayed on the display assembly of the present invention.

FIG. 20 is a flowchart illustrating the subprocess of transitioning the displayed single image on the display assembly of the present invention from a single floor to another floor of the building project.

FIG. 21 is a flowchart illustrating the subprocess of transitioning the displayed single image on the display assembly of the present invention from a single floor to an outdoor section of the building project.

FIG. 22 is a flowchart illustrating the subprocess of transitioning the displayed single image on the display assembly of the present invention from an outdoor section to a single floor of the building project.

FIG. 23 is a flowchart illustrating the subprocess of transitioning the displayed single image on the display assembly of the present invention between adjacent floors of the building project.

### DETAIL DESCRIPTIONS OF THE INVENTION

All illustrations of the drawings are for the purpose of describing selected versions of the present invention and are not intended to limit the scope of the present invention.

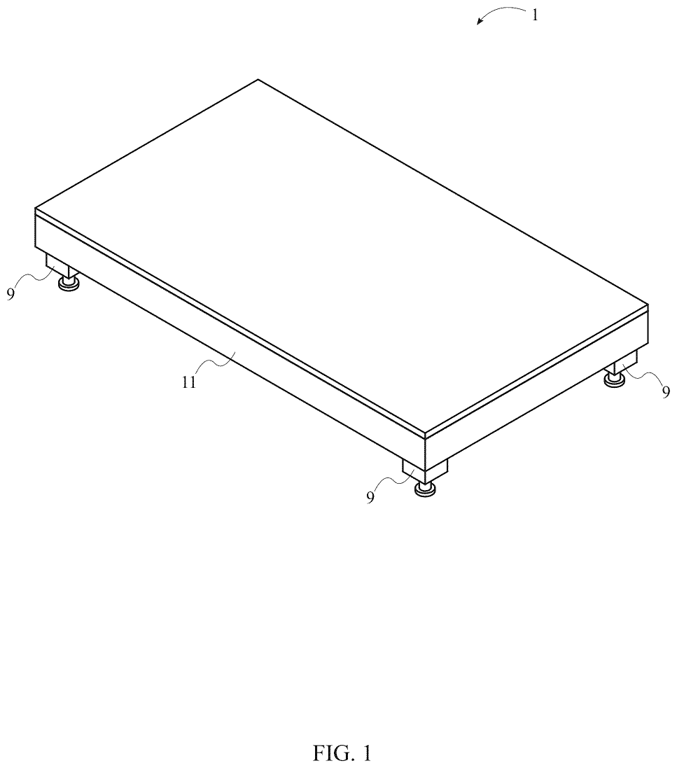

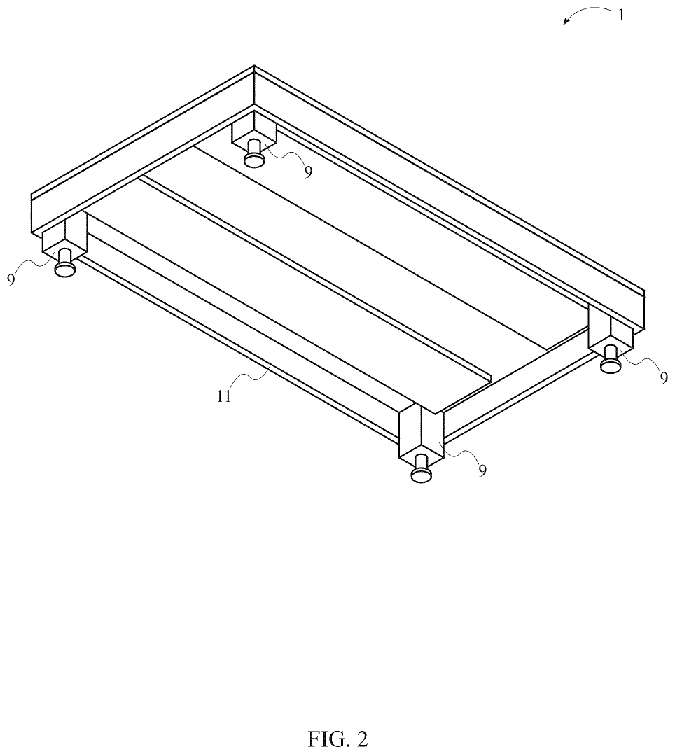

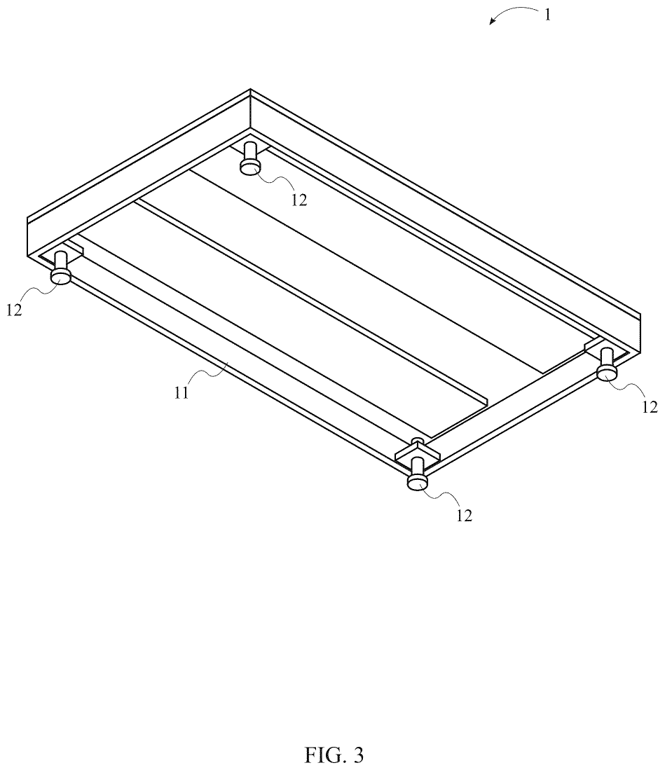

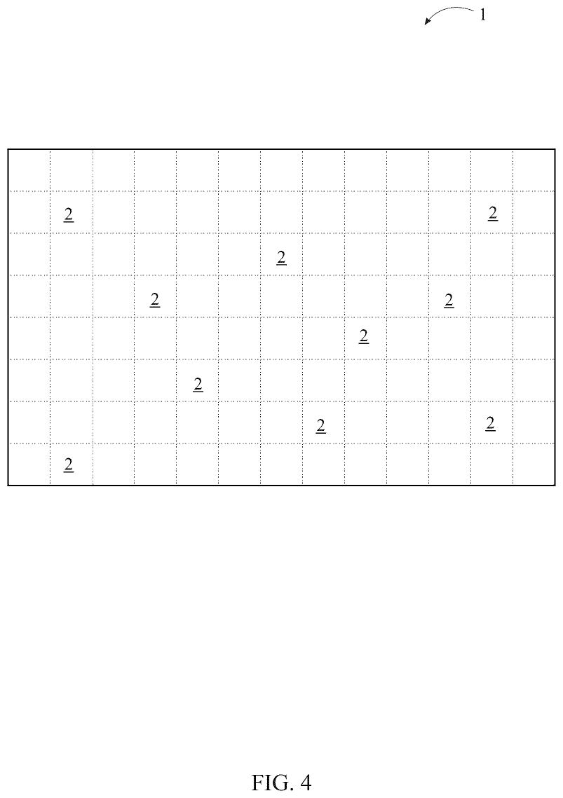

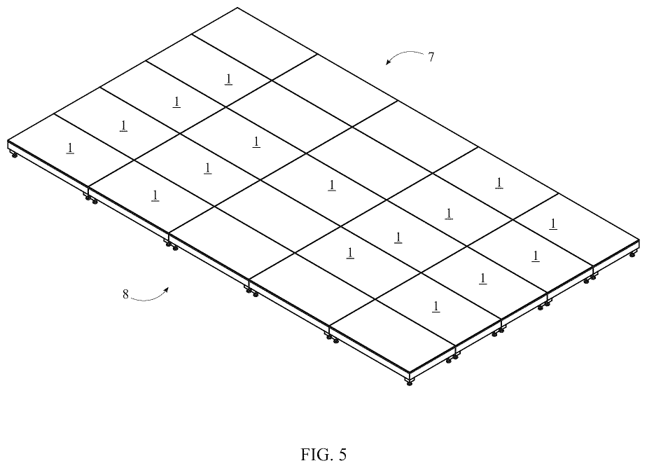

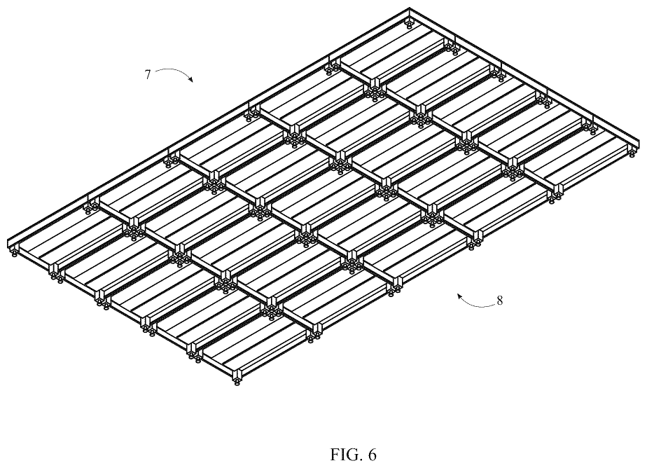

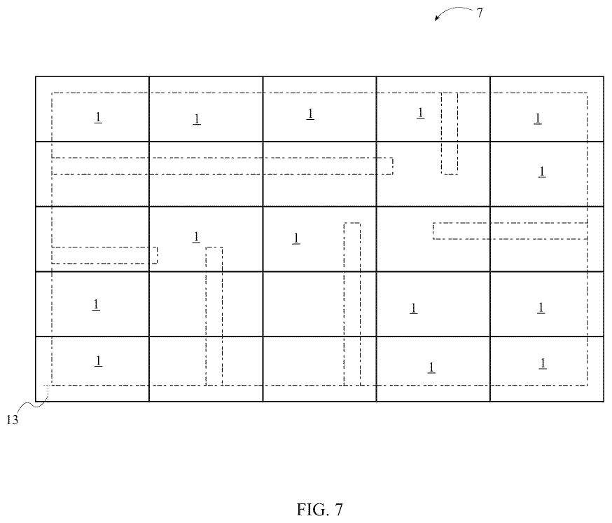

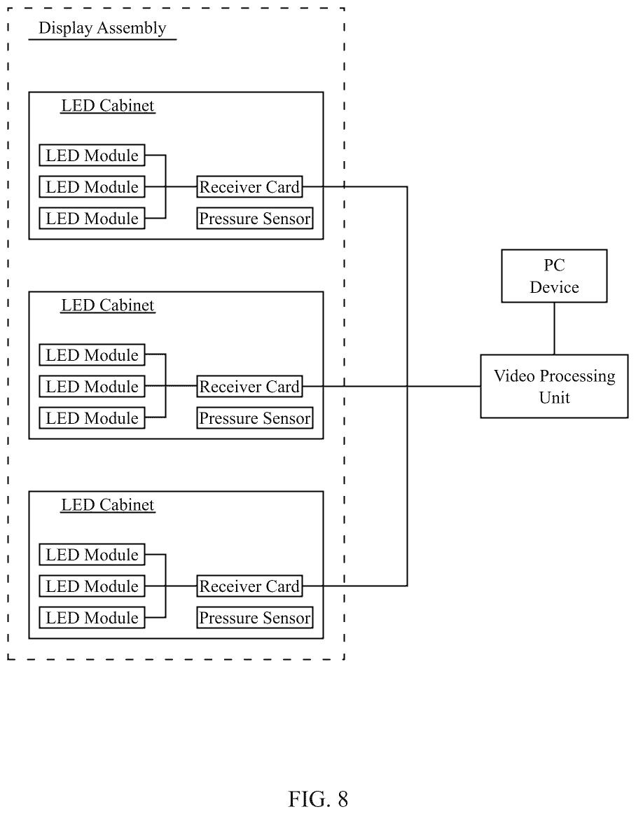

The present invention discloses a system and method of imaging a construction plan onto a walkable area that enables the user to experience and visualize a construction plan as how the construction plan would look like on the actual construction site. As can be seen in FIGS. 1 through 8, the present invention enables the display of different construction plan details that can be edited on site without obstructions, such as shadows, that could prevent the clear display of the construction plan details. Further, the present invention enables various types of construction plans to be displayed including, but not limited to, a site plan, a dimensional control plan, a furniture layout plan, a civil engineering design plan, an architectural blueprint, an elevation plan, an electrical plan, a Heating, Ventilation, and Air Conditioning (HVAC) plan, a mechanical plan, a plumbing plan, or a combination thereof.

As can be seen in FIGS. 1 through 8, the system of the present invention generally includes a plurality of light-emitting diode (LED) cabinets 1, a video processing unit 4, and a Personal computing (PC) device 5 (Step A). The plurality of LED cabinets 1 corresponds to several display structures designed to be deployed on the area where the project is going to be constructed. Each LED cabinet 1 is designed with a supporting frame that is strong enough to support the electronics of the LED cabinet 1 as well as the user walking on the LED cabinet 1. Further, each LED cabinet 1 comprises a plurality of LED modules 2 and a receiver card 3. The plurality of LED modules 2 includes several LED arrays that display the image corresponding to a graphical digital representation of a section of the construction plan. For example, each LED cabinet 1 can be equipped with six pixels to ensure consistent display quality, maintaining an undistorted preview even if individual pixels are affected. The receiver card 3 enables the transmission of the image signals from the PC device 5 to the corresponding LED cabinet 1. In addition, the receiver card 3 enables the relay of image signal to the corresponding LED module 2 to display the corresponding section of the construction plan. Further, the LED modules 2 are coincident with a walkable area so that each LED module 2 can be accessed by the user when walking around the displayed construction plan. In addition, the PC device 5 may be any computing device including, but not limited to, a desktop computer, a notebook computer, a tablet computer, a mobile device, etc. The PC device 5 allows for user input to control and manage what is outputted with each of the LED cabinets 1. Further, the PC device 5 includes different software applications including, but not limited to, architectural software, Autodesk BIM 360, Procore, or a combination thereof. Further, each of the software applications can be powered by Artificial Intelligence (AI) and/or machine learning.

As can be seen in FIGS. 1 through 8, the system of the present invention is set up so that the plurality of LED cabinets 1 can be arranged to form a walkable platform that matches the overall shape of the construction plan. In the preferred embodiment, the walkable platform is a designated walkable digital space that displays the construction plan in a 1:1 aspect ratio on both the X and Y axis. This way, the system can generate a life-sized representation of architectural blueprints while also enabling varying zoom levels and scales from 1:1 to 1:48, thereby ensuring flexibility in viewing from diverse perspectives. The user can walk upon the walkable platform when viewing the outputted image from the plurality of LED cabinets 1 ensuring a shadow-free experience. In addition, the real-time manipulation of the construction plan using the present invention offers the capability of the displayed plan elements to be freely moved and positioned at desired locations to facilitate economical deployment and adaptability of the displayed construction plan.

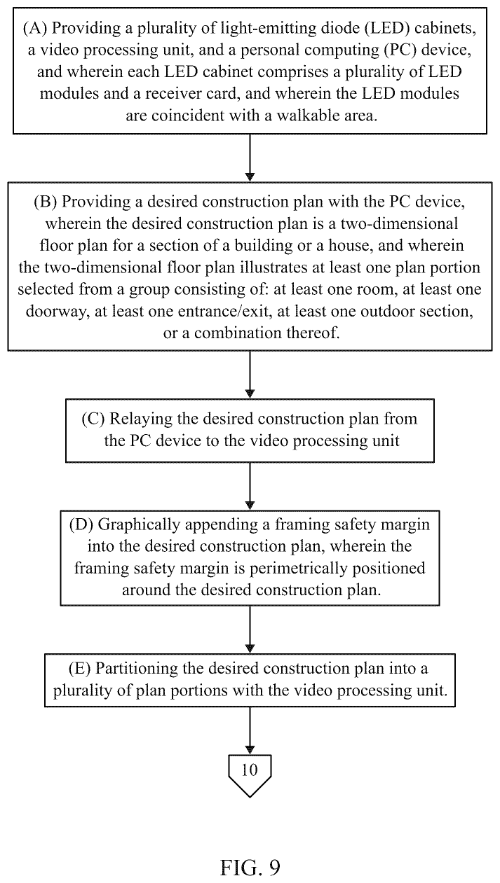

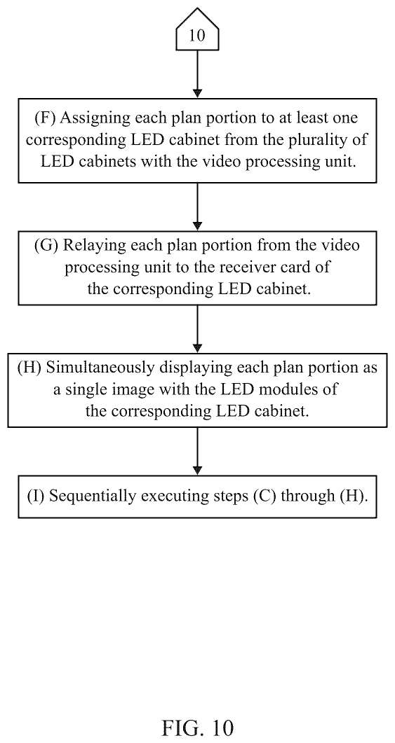

The method of the present invention follows an overall process that provides a digital imaging of a construction plan onto the walkable platform formed by the plurality of LED cabinets 1. As can be seen in FIGS. 9 and 10, the overall process begins by providing a desired construction plan with the PC device 5 (Step B). In general, the desired construction plan is a two-dimensional floor plan for a section of a building, a house, or other construction project. In addition, the two-dimensional floor plan illustrates at least one plan portion selected from a group consisting of: at least one room, at least one doorway, at least one entrance/exit, at least one outdoor section, or a combination thereof. In other words, the desired construction plan includes several plan portions corresponding to rooms, exits, entrances, or other similar architectural features that have been implemented into the desired construction plan. Each plan portion of the desired construction plan is processed and digitally rendered to create a digital version of the desired construction plan that can be displayed by the plurality of LED cabinets 1. Further, the digital version of the desired construction plan can be created using the PC device 5 or with an external computing device. When created using an external computing device, the digital version of the desired construction plan is relayed from the external computing device to the PC device 5 before Step B. In addition, the digital version of the desired construction plan can be provided in different formats. For example, the digital construction plan can be output in the form of a vector graphics file, supporting dynamic adjustment of the construction plan, and moving to display dimensionally accurate. Furthermore, the generation of the digital version of the desired construction plan can be performed using AI or other software program that automates the generation of the digital construction plan.

As can be seen in FIGS. 9 and 10, once the desired construction plan is generated and stored by the PC device 5, the desired construction plan is then relayed from the PC device 5 to the video processing unit 4 (Step C), if the desired floor plan is designated with the PC device 5. The video processing unit 4 processes the desired construction plan according to predetermined user settings so that the desired construction plan can be displayed by the LED cabinets 1. Further, the video processing unit 4 allows the user to edit the desired construction plan based on user input with the PC device 5. For example, the user can add or remove plan objects, change dimension, rearranged plan objects, etc. Further, most construction sites can be dangerous for the user to navigate due to various hazards present during the project's construction. So, a framing safety margin 13 is graphically appended into the desired construction plan (Step D) to provide a graphical safety indicator for the user to stay within the perimeter of the walkable platform formed by the LED cabinets 1. The framing safety margin 13 is perimetrically positioned around the desired construction plan so that the user can keep track of the perimeter of the desired construction plan.

Once the desired construction plan has been developed and adjusted according to the user's input, the video processing unit 4 then partitions the desired construction plan into a plurality of plan portions with the video processing unit 4 (Step E), as can be seen in FIGS. 9 and 10. The plurality of plan portions is preferably a set of image pieces that make up the desired floor plan displayed by the plurality of LED cabinets 1. Further, the video processing unit 4 assigns each plan portion to at least one corresponding LED cabinet from the plurality of LED cabinets 1 for execution and monitoring with the video processing unit 4 (Step F). In other words, the partitioned plan portions are assigned to specific LED cabinets 1 to ensure that each partitioned plan portion is displayed at a location that matches the desired construction plan. AI tools can also offer enhanced support for prompt relaying of instructions and use input if voice capacity is enabled. Once the partitioned plan portions are assigned to the corresponding LED cabinets 1, each plan portion from the video processing unit 4 is relayed to the receiver card 3 of the corresponding LED cabinet 1 (Step G). Different communication protocols can be utilized to relay the data between the different computing devices in the system. For example, a wireless network can be implemented to enable the wireless transmission of data. Alternatively, the different computing devices can be hardwired to each other to enable the wired transmission of data.

As can be seen in FIGS. 9 and 10, once the partitioned plan portions have been relayed to the corresponding LED cabinets 1, each plan portion is simultaneously displayed with the LED modules 2 of the corresponding LED cabinet 1 (Step F). The simultaneous display of the partitioned plan portions as a single image on the walkable area facilitate collaborative visualization of the desired construction plan as all users can visualize the same desired construction plan. Thus, an individual may view a floor plan while traversing across the walkable area. Finally, Steps C through H are sequentially executed to enable the successful display of the desired construction plan on the walkable platform formed with the plurality of LED cabinets 1.

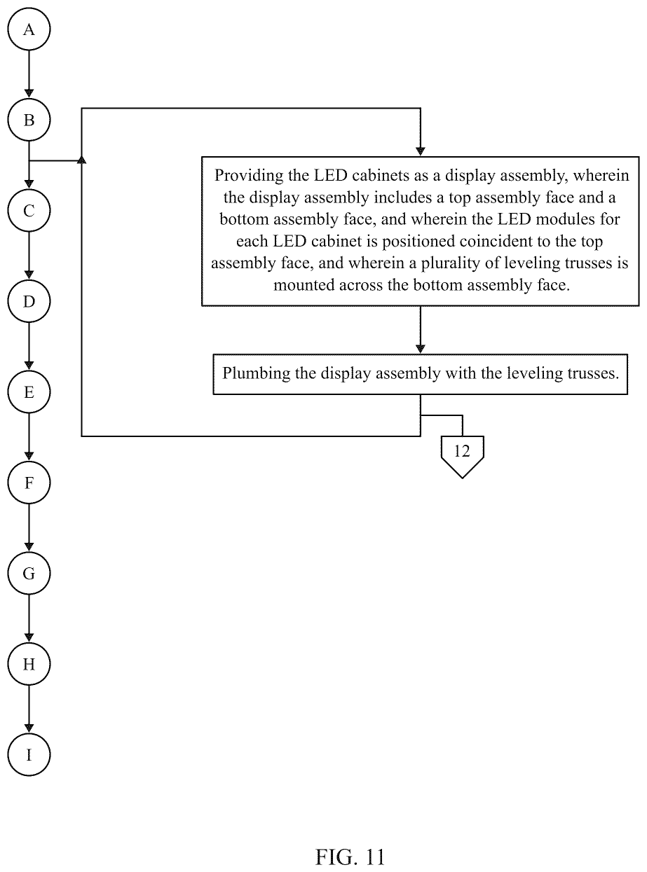

In order to continuously stabilize the walkable area as the user walks across the walkable area, the following subprocess is executed. As can be seen in FIGS. 1 through 8 and 11, the plurality of LED cabinets 1 is provided as a display assembly 6. In more detail, the display assembly 6 is a frame that borders and houses the plurality of LED modules 2. The display assembly 6 includes a top assembly face 7 and a bottom assembly face 8. The plurality of LED modules 2 for each LED cabinet 1 is positioned coincident to the top assembly face 7, and a plurality of leveling trusses 9 is mounted across the bottom assembly face 8. The plurality of leveling trusses 9 utilizes effective synchronization mechanisms to ensure the walkable LED platform maintains precise alignment, thereby preserving the accurate display of the floor plan even amidst vibrations and other dynamic movements and preventing image blending or image distortion. The plurality of leveling trusses 9 is preferably a set of mechanical stabilizers that continuously keeps the walkable area at leveled on the ground. For example, each of the leveling trusses 9 can be a linear actuator that can automatically engage to raise the corresponding portion of the display assembly 6 off the ground. The display assembly 6 is plumbed with the plurality of leveling trusses 9 to connect each leveling truss to the corresponding display assembly 6. Thus, the walkable area is continuously kept leveled prevent a user from stumbling when walking across the walkable area. This configuration facilitates easy assembly for maintenance and disassembly of individual LED cabinets 1 and enables independent movement of LED cabinets 1, promoting cost-efficiency and eliminating the need for extensive labor.

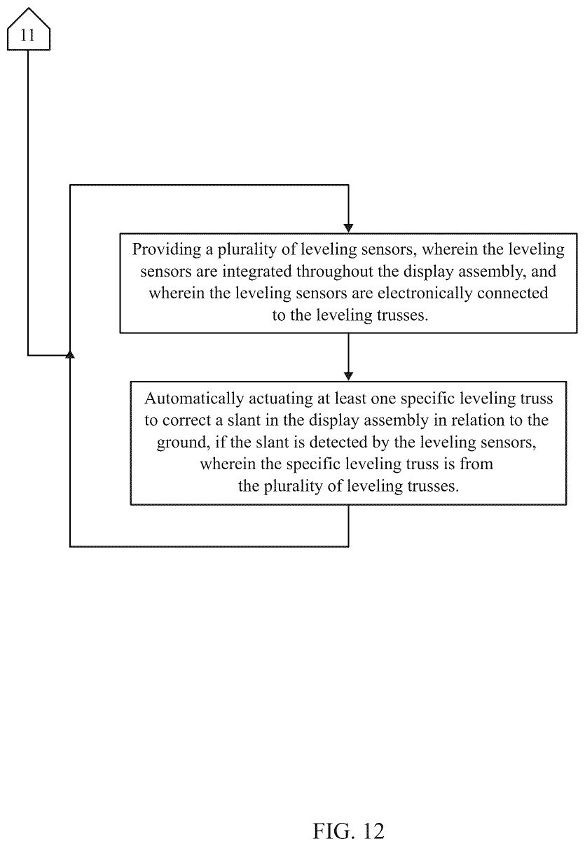

As can be seen in FIGS. 1 through 8 and 12, to further facilitate the leveling of the walkable platform formed with the LED cabinets 1, the system of the present invention may further include a plurality of leveling sensors 10 that help monitor the current level of the walkable platform. The leveling sensors 10 are integrated throughout the display assembly 6, and the leveling sensors 10 are electronically connected to the leveling trusses 9 so that the corresponding sensor signals are relayed to the leveling trusses 9. Further, the subprocess of automatically leveling the display assembly 6 includes the step of automatically actuating at least one specific leveling truss to correct a slant in the display assembly 6 in relation to the ground, if the slant is detected by the leveling sensors 10, wherein the specific leveling truss is from the plurality of leveling trusses 9. This way, the entire walkable platform is maintained leveled so that the user can safely walk around the walkable platform.

In the preferred embodiment, the plurality of leveling trusses 9 is designed to elevate the display assembly 6 off the ground so that the walkable platform can be properly leveled. As can be seen in FIGS. 1 through 8, the display assembly 6 can be evenly positioned offset from a ground by the leveling trusses 9 to facilitate the leveling of the display assembly 6. In addition, the leveling trusses 9 can be peripherally distributed around the bottom assembly face 8 to provide appropriate structural support to the display assembly 6. This way, the leveling trusses 9 can efficiently level the overall display assembly 6 once the display assembly 6 has been assembled to form the walkable platform. In other embodiments, different types of leveling devices can be implemented and can be arranged into different configurations according to the type of leveling device being implemented.

In an alternate embodiment, the LED cabinets 1 can be designed so that the user can manually level each LED cabinet. As can be seen in FIGS. 1 through 8, each LED cabinet 1 may further comprise a modules-setting structure 11 and a plurality of leveling mounts 12. The modules-setting structure 11 and the leveling mounts 12 enable the user to manually set up the display assembly 6. To do so, the LED modules 2 are arranged in a planar grid configuration, and the LED modules 2 are attached into the modules-setting structure 11 by the leveling mounts 12. This way, the display assembly 6 can be manually set up. In addition, the LED modules 2 are evenly positioned offset from a ground by the plurality of leveling mounts 12 to enable the leveling of the display assembly 6 using each leveling mount. Further, the leveling mounts 12 are peripherally distributed around the modules-setting structure 11 to provide appropriate structural support to the display assembly 6.

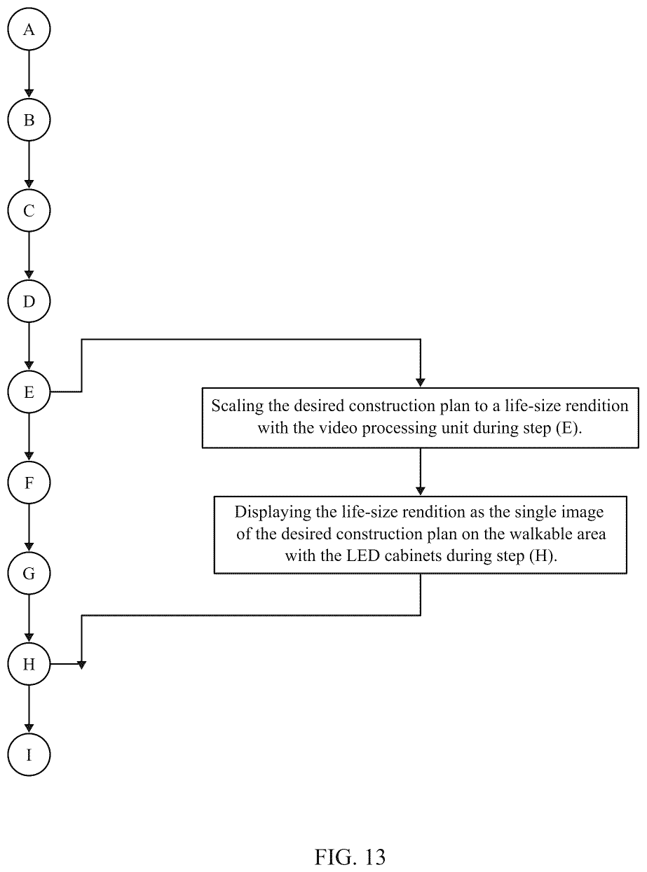

In order to output the single image as a 1:1 scaled image, the following subprocess is executed. As can be seen in FIG. 13, the video processing unit 4 scales the desired construction plan to a life-size rendition during Step E. The life-size rendition is a 1:1 scaled version of the desired construction plan. In addition, the plurality of LED cabinets 1 display the life-size rendition as the single image of the desired construction plan on the walkable area during Step H. Thus, the single image is outputted as a 1:1 scaled design.

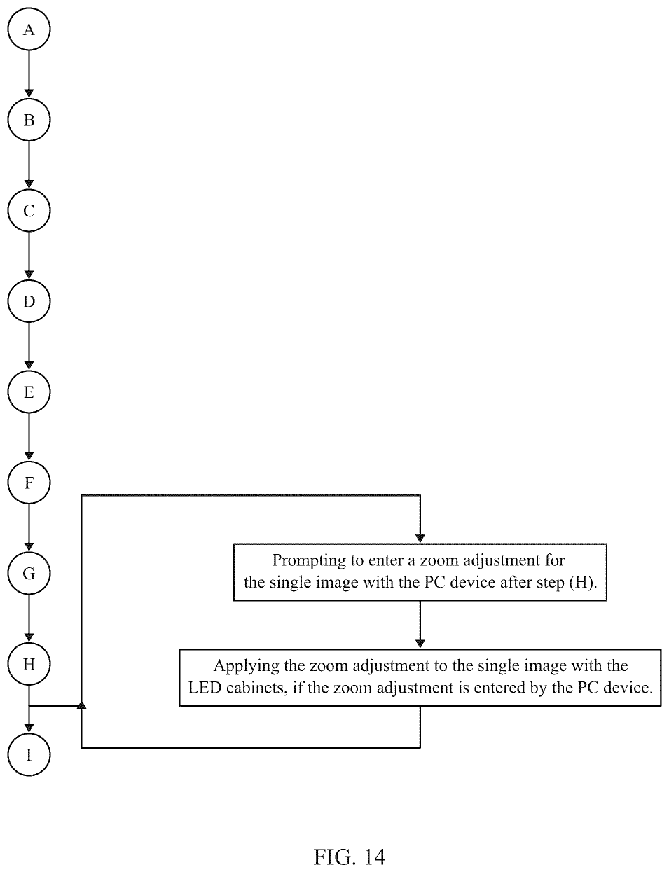

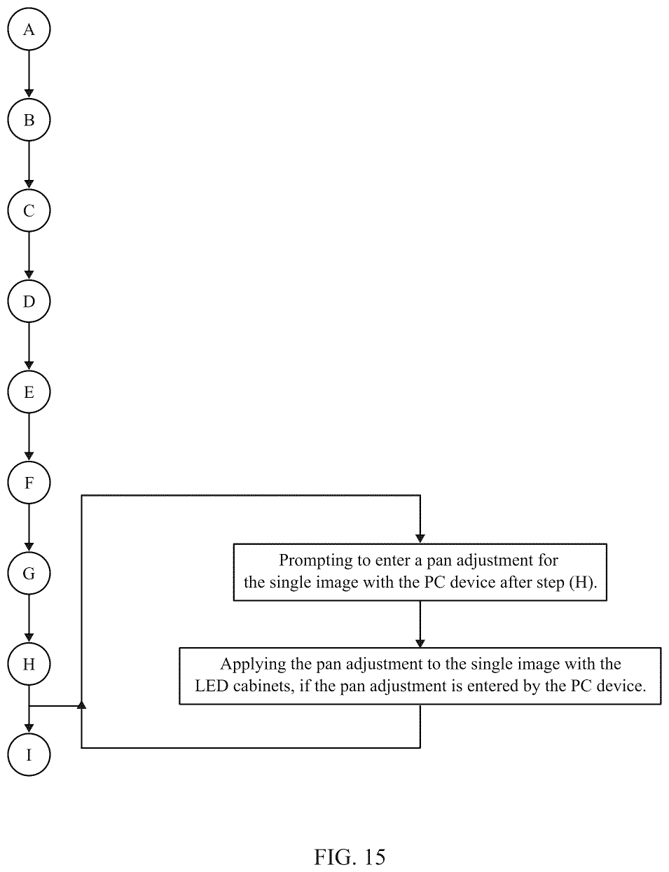

In order to allow panning or zooming of the single image, the following subprocess is executed. As can be seen in FIGS. 14 and 15, the PC device 5 prompts the user to enter a pan adjustment and/or zoom adjustment for the single image after Step H. The pan adjustment is an input that allows a user to move the single image in a linear direction. The zoom adjustment is an input that allows a user to zoom into or out of the single image. Further, the zoom adjustment is applied to the single image with the LED cabinets 1, if the zoom adjustment is entered by the PC device 5. Similarly, the pan adjustment is applied to the single image with the LED cabinets 1, if the pan adjustment is entered by the PC device 5. Thus, a user can better view a specified section of the single image by panning around and gliding across the single image.

The real-time editing features of the present invention allow for different functions to be applied for the user to better visualize the desired construction plan. For example, this functionality allows real-time modifications to the desired construction plan, accommodations of construction plans larger than the display assembly 6, precise architectural detail representation, and usability across various blueprint scales. Additionally, the zoom adjustment feature can enable the user to view the desired construction plan from different perspectives. For example, the zoom adjustment feature can mimic viewing the single image from a mezzanine deck. The mezzanine deck view offers a bird's-eye view, providing users with an overall grid view to remotely experience and interact with the floor plan. Further, the zoom adjustment feature can include different ranges of zoom capabilities. For example, the zoom adjustment can range between a 1:1 viewing ratio to a 1:48 viewing ratio. In other embodiments, different live-editing features can be implemented.

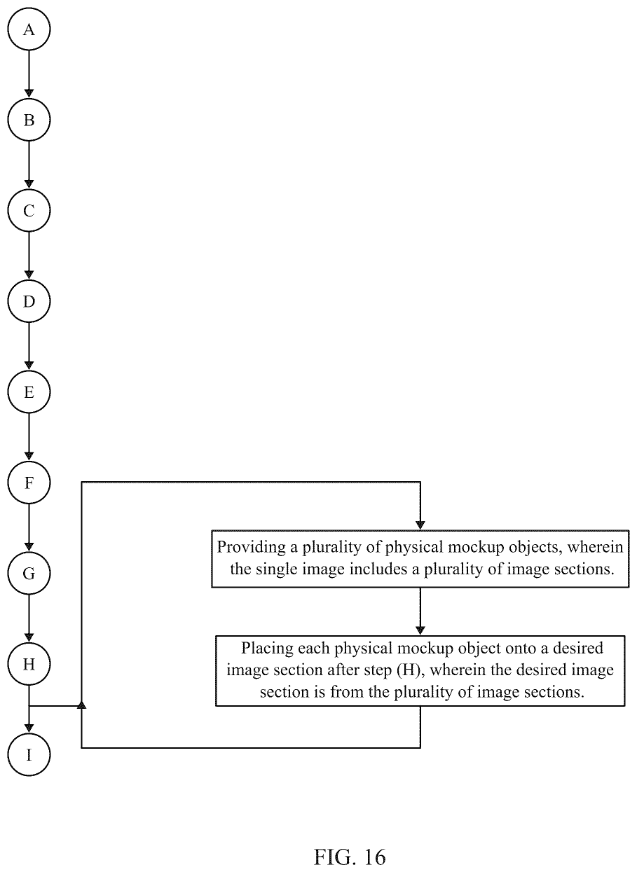

In order to further detail the construction plan with physical mockup objects, the following subprocess is executed. As can be seen in FIG. 16, a plurality of physical mockup objects is provided, and the single image includes a plurality of image sections. The plurality of image sections is a set of specific pieces of the single image. The plurality of physical mockup objects may be any type of mockup object such as, but not limited to, mockup furniture, mockup walls, mockup stairs, or mockup vehicles. Each physical mockup object is placed onto a desired image section after Step H. The desired image section is from the plurality of image sections. Thus, the construction plan is further detailed with mockup objects.

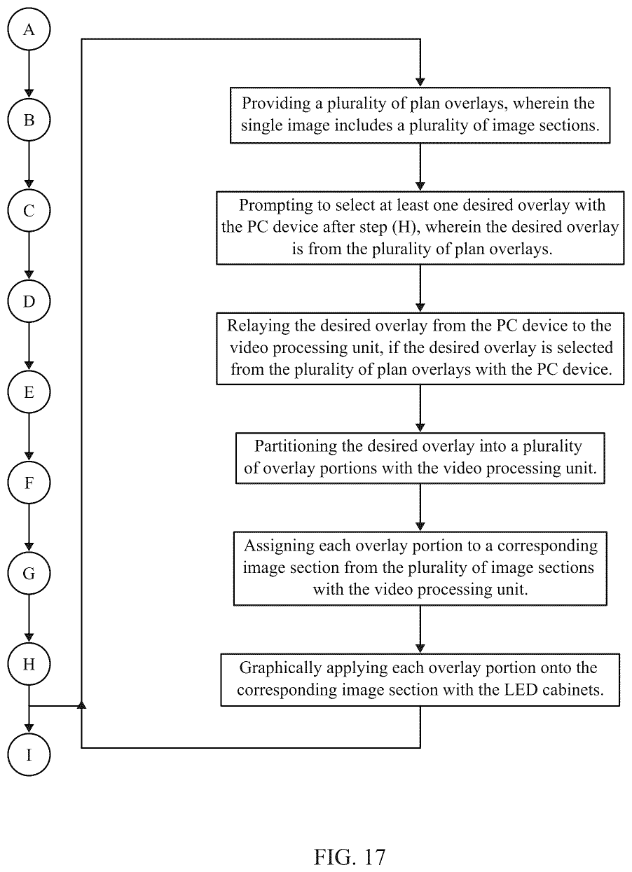

Alternatively, the construction plan can be further detailed with the use of digital overlays. As can be seen in FIG. 17, a plurality of plan overlays is provided. The plurality of plan overlays can be any type of digital overlay such as, but not limited to, a color-coding overlay, a texture overlay, a picture overlay, a furniture layout overlay, a mechanical, electrical, and plumbing (MEP) layout overlay, a photometric layout overlay, or combinations thereof. In addition, the single image includes a plurality of image sections corresponding to different image sections displayed by each LED cabinet 1. The PC device 5 prompts the user to select at least one desired overlay after Step H. The desired overlay is from the plurality of plan overlays available for the desired construction plan. Then, the desired overlay is relayed from the PC device 5 to the video processing unit 4, if the desired overlay is selected from the plurality of plan overlays with the PC device 5. Thus, the video processing unit 4 can manage the desired overlay. The video processing unit 4 then partitions the desired overlay into a plurality of overlay portions. The plurality of overlay portions is a set of graphical divisions that make up the desired overlay. The video processing unit 4 assigns each overlay portion to a corresponding image section from the plurality of image sections. This step allows the desired overlay to be properly displayed onto the single image. Finally, the corresponding LED cabinets 1 graphically applies each overlay portion onto the corresponding image section. Thus, the desired construction plan displayed on the display assembly 7 is further detailed with the desired overlay.

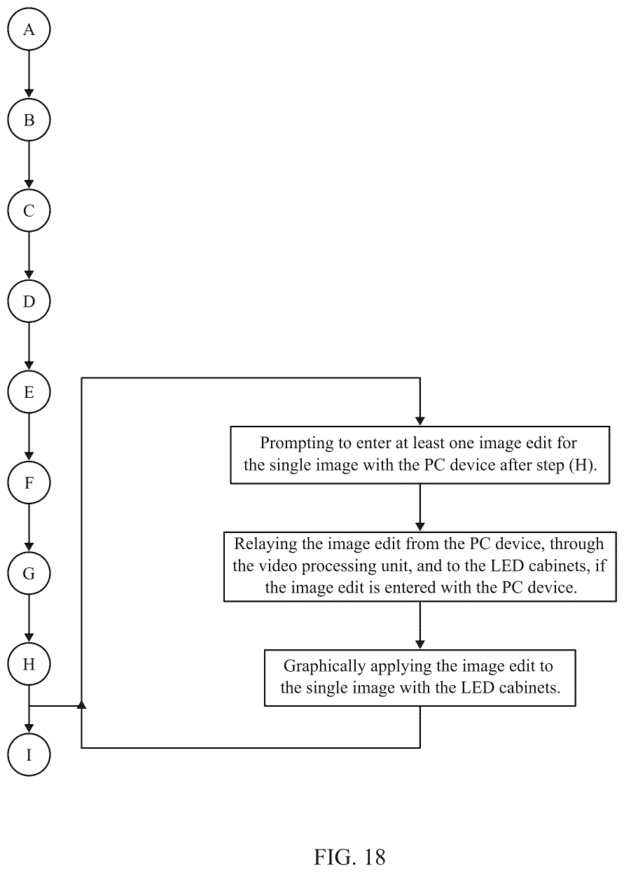

In order for the construction plan to be edited in real-time, the following subprocess is executed. As can be seen in FIG. 18, the PC device 5 prompts the user to enter at least one image edit for the single image after Step H. The image edit may be any type of edit such as, but not limited to, a change in the specifications of the construction plan, an edit to hide unnecessary details, unwind bottlenecks, refine dimensions, and/or redrawing of the construction plans. In addition, the image edit can be performed using different editing software and/or AI tools. Further, the image edit is relayed from PC device 5, through the video processing unit 4, and to the LED cabinets 1, if the image edit is entered with the PC device 5. The image edit may go through further processing including, but not limited to, editing software and AI to refine the construction plan, edits measured for accuracy, etc., so that the user can make informed decision simultaneously. Finally, the plurality of LED cabinets 1 graphically applies the image edit to the single image. Thus, the construction plan is edited in real-time.

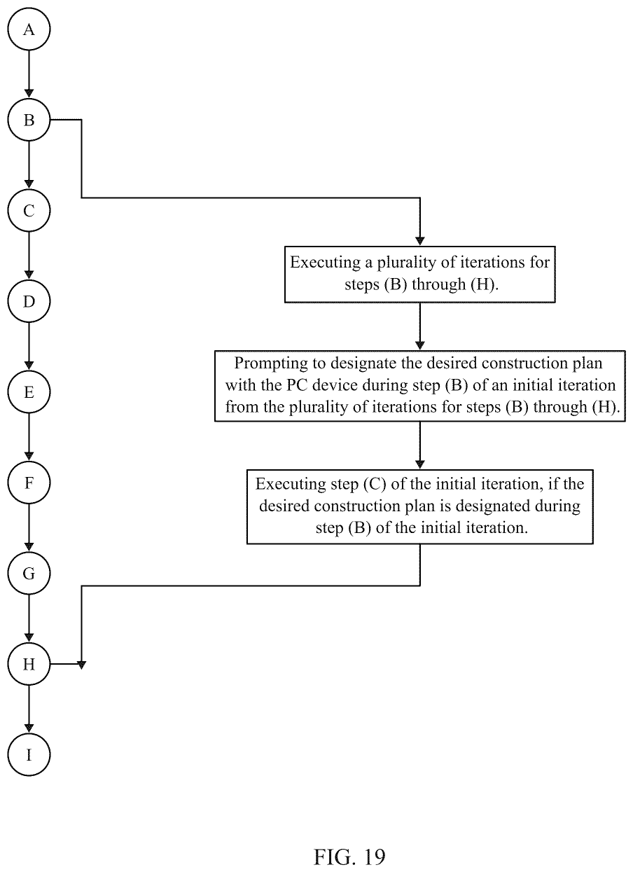

As previously discussed, the present invention enables the user to select a construction plan from different construction plans available for the desired project. As can be seen in FIG. 19, the subprocess of enabling the user to select a desired construction plan includes the steps of executing a plurality of iterations for Steps B through H. During each iteration, the user is prompted to designate the desired construction plan with the PC device 5 during Step B of an initial iteration from the plurality of iterations for Steps B through H. In other words, the user can select different construction plans by resetting the system and applying a different construction plan. Then, Step C of the initial iteration is executed, if the desired construction plan is designated during Step B of the initial iteration. This subprocess can be repeated as necessary if the user desires to visualize different construction plans on the display assembly 6.

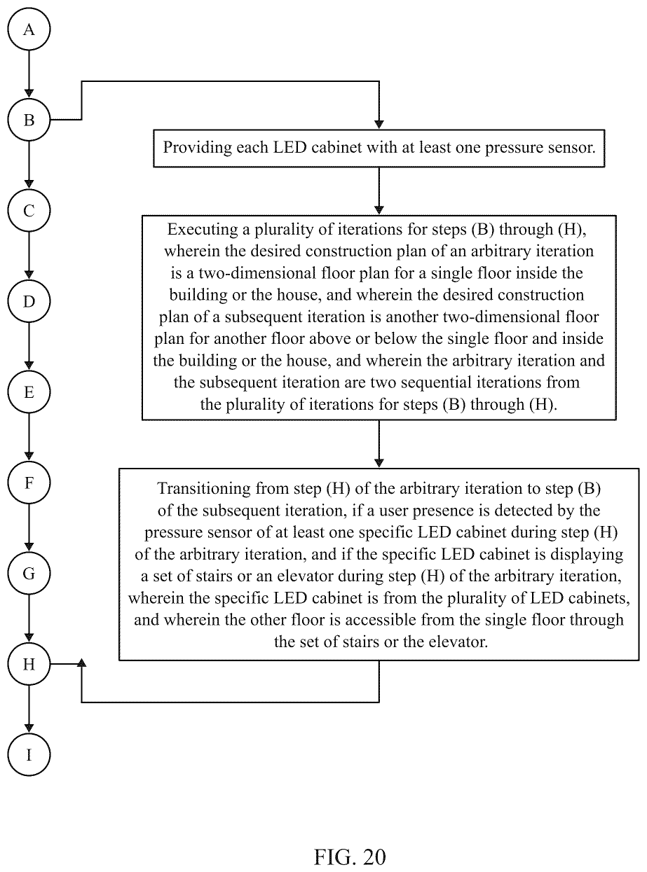

The system of the present invention enables the user to interact with the construction plan as if the user were walking through the construction project. As can be seen in FIG. 20, the system of the present invention may provide each LED cabinet 1 with at least one pressure sensor that is able to generate a pressure signal once the user steps on the corresponding LED cabinet 1. This way, the pressure sensors can be used to change the desired construction plan graphically depending on the LED cabinet 1 the user steps on. For example, the selected construction plan can display different building floors of a building or other multi-floor project. The subprocess of displaying different building floors using the same display assembly 6 includes the steps of executing a plurality of iterations for Steps B though H. In this embodiment, the desired construction plan of an arbitrary iteration is a two-dimensional floor plan for a single floor inside the building or the house. In addition, the desired construction plan of a subsequent iteration is another two-dimensional floor plan for another floor above or below the single floor and inside the building or the house. In other words, each iteration of the process can display a different floor of the project so that the user can fully visualize the entirety of the project. Further, the arbitrary iteration and the subsequent iteration are two sequential iterations from the iterations for Steps B through H.

In addition, As can be seen in FIG. 20, during each iteration for Steps B through H, Step H of the arbitrary iteration can transition to Step B of the subsequent iteration, if a user presence is detected by the pressure sensor of at least one specific LED cabinet 1 during Step H of the arbitrary iteration. In other words, if the user steps on the specific LED cabinet 1 during the arbitrary iteration, the displayed single image of a building floor is switched to the next building floor of the desired construction plan. In addition, the specific LED cabinet 1 can correspond to specific architectural features of the building project, such as a set of stairs or an elevator. For example, the specific LED cabinet 1 can be displaying a set of stairs or an elevator during Step H of the arbitrary iteration. Further, for the displayed single image to change, the other floor must be accessible from the single floor through the set of stairs or the elevator.

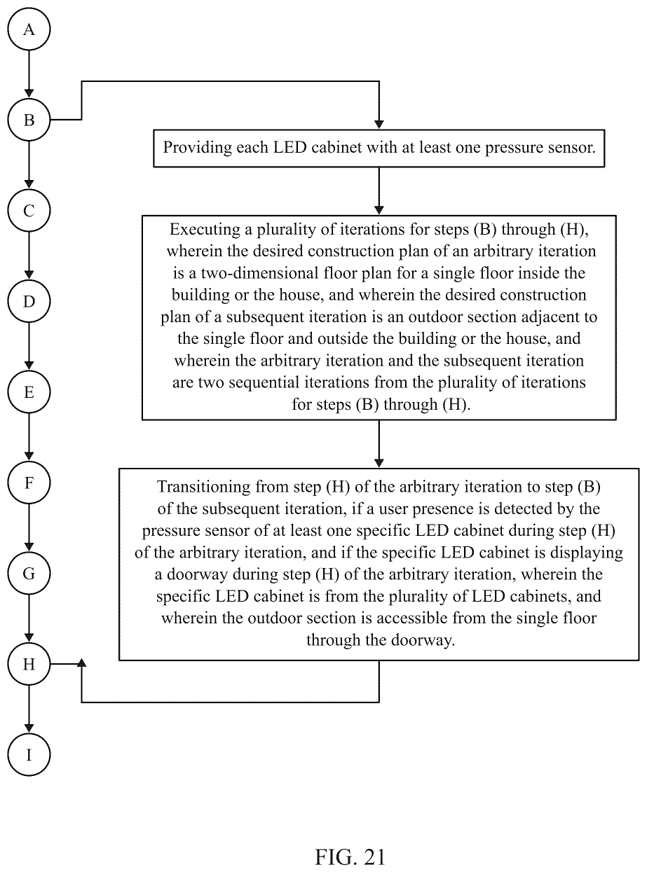

Further, the pressure sensors can be used to display other external features of the building project, such as a garden, backyard, etc. As can be seen in FIG. 21, the desired construction plan of the subsequent iteration can be an outdoor section adjacent to the single floor and outside the building or the house. Then, during each iteration for Steps B through H, Step H of the arbitrary iteration transitions to Step B of the subsequent iteration, if a user presence is detected by the pressure sensor of at least one specific LED cabinet 1 during Step H of the arbitrary iteration. In addition, the specific LED cabinet 1 can correspond to specific architectural features of the building project, such as a doorway. For example, if the specific LED cabinet 1 can be displaying a doorway during Step H of the arbitrary iteration. Further, for the displayed single image to change, the outdoor section must be accessible from the single floor through the doorway.

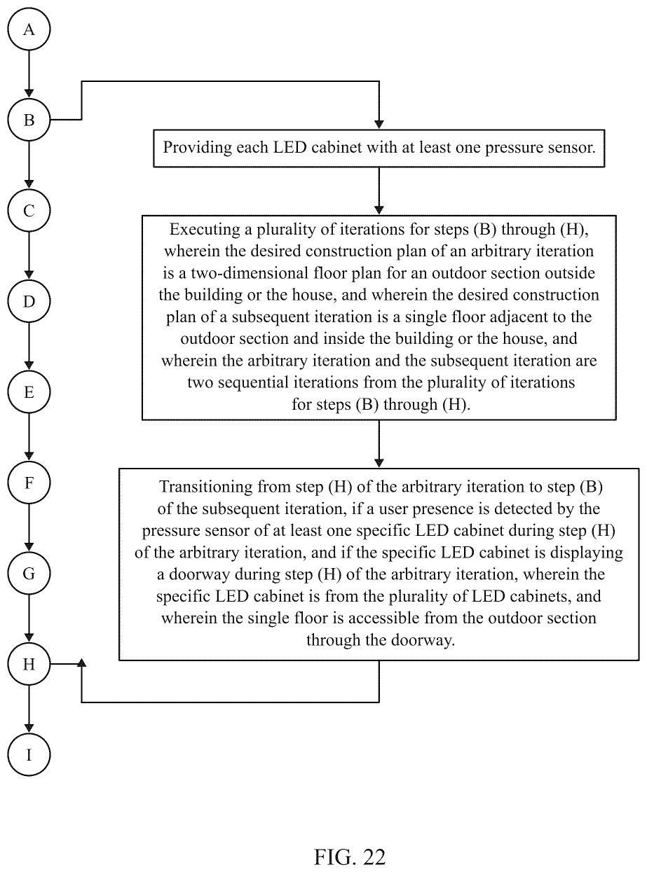

In addition, the present invention can also enable the user to transition from the outdoor section to the interior of the building project. As can be seen in FIG. 22, during each iteration for Steps B through H, Step H of the arbitrary iteration transitions to Step B of the subsequent iteration, if a user presence is detected by the pressure sensor of at least one specific LED cabinet 1 during Step H of the arbitrary iteration, and if the specific LED cabinet 1 displays a doorway during Step H of the arbitrary iteration. Further, for the displayed single image to change, the single floor must be accessible from the outdoor section through the doorway.

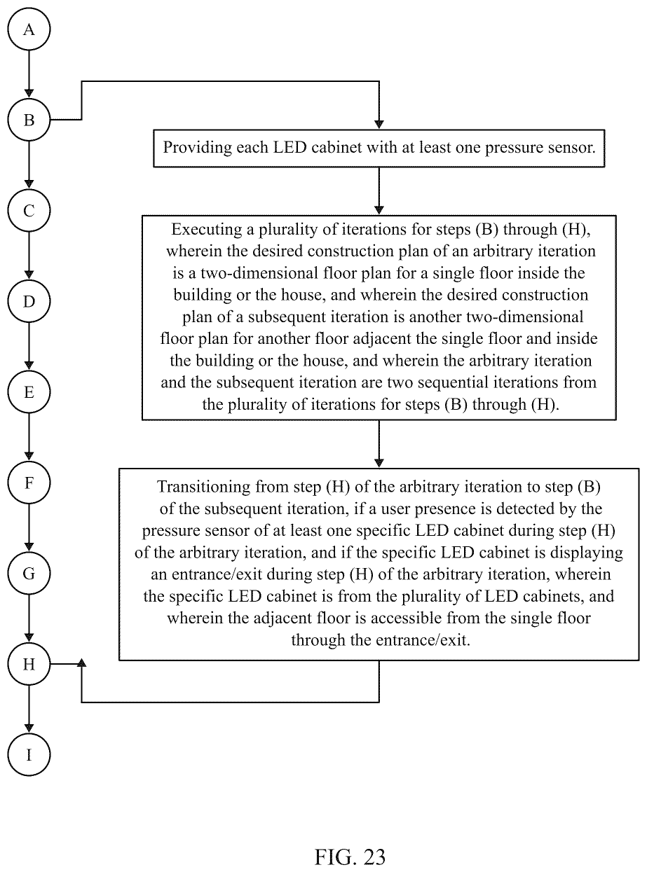

Furthermore, the present invention can also enable the user to transition between interior adjacent floors inside the building project. For example, the arbitrary iteration is a two-dimensional floor plan for a single floor inside the building or the house, and the desired construction plan of a subsequent iteration is another two-dimensional floor plan for another floor adjacent the single floor and inside the building or the house. As can be seen in FIG. 23, the transition between the adjacent interior floors of the building project can be triggered through graphical representations of an entrance and/or exit. To enable the transition, during each iteration for Steps B through H, Step H of the arbitrary iteration transitions to Step B of the subsequent iteration, if a user presence is detected by the pressure sensor of at least one specific LED cabinet 1 during Step H of the arbitrary iteration, and if the specific LED cabinet 1 displays an entrance/exit during Step H of the arbitrary iteration. Further, for the displayed single image to change, the adjacent floor must be accessible from the single floor through the entrance/exit. In other embodiments, different architectural features can be implemented that can be visualized using the present invention.

Although the invention has been explained in relation to its preferred embodiment, it is to be understood that many other possible modifications, with emerging technologies, and variations can be made without departing from the spirit and scope of the invention as hereinafter claimed.

What is claimed is:

1. A method of imaging a construction plan onto a walkable area, the method comprises the steps of:
(A) providing a plurality of light-emitting diode (LED) cabinets, a video processing unit, and a personal computing (PC) device, and wherein each LED cabinet comprises a plurality of LED modules and a receiver card, and wherein the LED modules are coincident with a walkable area;
(B) providing a desired construction plan with the PC device, wherein the desired construction plan is a two-dimensional floor plan for a section of a building or a house, and wherein the two-dimensional floor plan illustrates at least one plan portion selected from a group consisting of: at least one room, at least one doorway, at least one entrance/exit, at least one outdoor section, or a combination thereof;
(C) relaying the desired construction plan from the PC device to the video processing unit;
(D) graphically appending a framing safety margin into the desired construction plan, wherein the framing safety margin is perimetrically positioned around the desired construction plan;
(E) partitioning the desired construction plan into a plurality of plan portions with the video processing unit;
(F) assigning each plan portion to at least one corresponding LED cabinet from the plurality of LED cabinets with the video processing unit;
(G) relaying each plan portion from the video processing unit to the receiver card of the corresponding LED cabinet;
(H) simultaneously displaying each plan portion as a single image with the LED modules of the corresponding LED cabinet; and
(I) sequentially executing steps (C) through (H).

2. The method of imaging a construction plan onto a walkable area, the method as claimed in claim 1 comprises the steps of:
providing the LED cabinets as a display assembly, wherein the display assembly includes a top assembly face and a bottom assembly face, and wherein the LED modules for each LED cabinet is positioned coincident to the top assembly face, and wherein a plurality of leveling trusses is mounted across the bottom assembly face; and
plumbing the display assembly with the leveling trusses.

3. The method of imaging a construction plan onto a walkable area, the method as claimed in claim 2 comprises the steps of:
providing a plurality of leveling sensors, wherein the leveling sensors are integrated throughout the display assembly, and wherein the leveling sensors are electronically connected to the leveling trusses; and
automatically actuating at least one specific leveling truss to correct a slant in the display assembly in relation to the ground, if the slant is detected by the leveling sensors, wherein the specific leveling truss is from the plurality of leveling trusses.

4. The method of imaging a construction plan onto a walkable area, the method as claimed in claim 2, wherein the display assembly is evenly positioned offset from a ground by the leveling trusses, and wherein the leveling trusses are peripherally distributed around the bottom assembly face.

5. The method of imaging a construction plan onto a walkable area, the method as claimed in claim 2, wherein the leveling trusses are a plurality of linear actuators.

6. The method of imaging a construction plan onto a walkable area, the method as claimed in claim 1, wherein each LED cabinet further comprises a modules-setting structure and a plurality of leveling mounts, and wherein the LED modules are arranged in a planar grid configuration, and wherein the LED modules are attached into the modules-setting structure by the leveling mounts, and wherein the LED modules are evenly positioned offset from a ground by the plurality of leveling mounts, and wherein the leveling mounts are peripherally distributed around the modules-setting structure.

7. The method of imaging a construction plan onto a walkable area, the method as claimed in claim 1 comprises the steps of:
scaling the desired construction plan to a life-size rendition with the video processing unit during step (E); and
displaying the life-size rendition as the single image of the desired construction plan on the walkable area with the LED cabinets during step (H).

8. The method of imaging a construction plan onto a walkable area, the method as claimed in claim 1 comprises the steps of:
prompting to enter a zoom adjustment for the single image with the PC device after step (H); and
applying the zoom adjustment to the single image with the LED cabinets, if the zoom adjustment is entered by the PC device.

9. The method of imaging a construction plan onto a walkable area, the method as claimed in claim 8, wherein the zoom adjustment mimics viewing the single image from a mezzanine deck.

10. The method of imaging a construction plan onto a walkable area, the method as claimed in claim 8, wherein the zoom adjustment ranges between a 1:1 viewing ratio to a 1:48 viewing ratio.

11. The method of imaging a construction plan onto a walkable area, the method as claimed in claim 1 comprises the steps of:
prompting to enter a pan adjustment for the single image with the PC device after step (H); and
applying the pan adjustment to the single image with the LED cabinets, if the pan adjustment is entered by the PC device.

12. The method of imaging a construction plan onto a walkable area, the method as claimed in claim 1 comprises the steps of:
providing a plurality of physical mockup objects, wherein the single image includes a plurality of image sections; and
placing each physical mockup object onto a desired image section after step (H), wherein the desired image section is from the plurality of image sections.

13. The method of imaging a construction plan onto a walkable area, the method as claimed in claim 1 comprises the steps of:
providing a plurality of plan overlays, wherein the single image includes a plurality of image sections;
prompting to select at least one desired overlay with the PC device after step (H), wherein the desired overlay is from the plurality of plan overlays;
relaying the desired overlay from the PC device to the video processing unit, if the desired overlay is selected from the plurality of plan overlays with the PC device;
partitioning the desired overlay into a plurality of overlay portions with the video processing unit;
assigning each overlay portion to a corresponding image section from the plurality of image sections with the video processing unit; and
graphically applying each overlay portion onto the corresponding image section with the LED cabinets.

14. The method of imaging a construction plan onto a walkable area, the method as claimed in claim 1 comprises the steps of:
prompting to enter at least one image edit for the single image with the PC device after step (H);
relaying the image edit from the PC device, through the video processing unit, and to the LED cabinets, if the image edit is entered with the PC device; and
graphically applying the image edit to the single image with the LED cabinets.

15. The method of imaging a construction plan onto a walkable area, the method as claimed in claim 1 comprises the steps of:
executing a plurality of iterations for steps (B) through (H);
prompting to designate the desired construction plan with the PC device during step (B) of an initial iteration from the plurality of iterations for steps (B) through (H); and
executing step (C) of the initial iteration, if the desired construction plan is designated during step (B) of the initial iteration.

16. The method of imaging a construction plan onto a walkable area, the method as claimed in claim 1 comprises the steps of:
providing each LED cabinet with at least one pressure sensor;
executing a plurality of iterations for steps (B) through (H), wherein the desired construction plan of an arbitrary iteration is a two-dimensional floor plan for a single floor inside the building or the house, and wherein the desired construction plan of a subsequent iteration is another two-dimensional floor plan for another floor above or below the single floor and inside the building or the house, and wherein the arbitrary iteration and the subsequent iteration are two sequential iterations from the plurality of iterations for steps (B) through (H); and
transitioning from step (H) of the arbitrary iteration to step (B) of the subsequent iteration, if a user presence is detected by the pressure sensor of at least one specific LED cabinet during step (H) of the arbitrary iteration, and if the specific LED cabinet is displaying a set of stairs or an elevator during step (H) of the arbitrary iteration, wherein the specific LED cabinet is from the plurality of LED cabinets, and wherein the other floor is accessible from the single floor through the set of stairs or the elevator.

17. The method of imaging a construction plan onto a walkable area, the method as claimed in claim 1 comprises the steps of:
providing each LED cabinet with at least one pressure sensor;
executing a plurality of iterations for steps (B) through (H), wherein the desired construction plan of an arbitrary iteration is a two-dimensional floor plan for a single floor inside the building or the house, and wherein the desired construction plan of a subsequent iteration is an outdoor section adjacent to the single floor and outside the building or the house, and wherein the arbitrary iteration and the subsequent iteration are two sequential iterations from the plurality of iterations for steps (B) through (H); and
transitioning from step (H) of the arbitrary iteration to step (B) of the subsequent iteration, if a user presence is detected by the pressure sensor of at least one specific LED cabinet during step (H) of the arbitrary iteration, and if the specific LED cabinet is displaying a doorway during step (H) of the arbitrary iteration, wherein the specific LED cabinet is from the plurality of LED cabinets, and wherein the outdoor section is accessible from the single floor through the doorway.

18. The method of imaging a construction plan onto a walkable area, the method as claimed in claim 1 comprises the steps of:
providing each LED cabinet with at least one pressure sensor;
executing a plurality of iterations for steps (B) through (H), wherein the desired construction plan of an arbitrary iteration is a two-dimensional floor plan for an outdoor section outside the building or the house, and wherein the desired construction plan of a subsequent iteration is a single floor adjacent to the outdoor section and inside the building or the house, and wherein the arbitrary iteration and the subsequent iteration are two sequential iterations from the plurality of iterations for steps (B) through (H); and
transitioning from step (H) of the arbitrary iteration to step (B) of the subsequent iteration, if a user presence is detected by the pressure sensor of at least one specific LED cabinet during step (H) of the arbitrary iteration, and if the specific LED cabinet is displaying a doorway during step (H) of the arbitrary iteration, wherein the specific LED cabinet is from the plurality of LED cabinets, and wherein the single floor is accessible from the outdoor section through the doorway.

19. The method of imaging a construction plan onto a walkable area, the method as claimed in claim 1 comprises the steps of:
providing each LED cabinet with at least one pressure sensor;
executing a plurality of iterations for steps (B) through (H), wherein the desired construction plan of an arbitrary iteration is a two-dimensional floor plan for a single floor inside the building or the house, and wherein the desired construction plan of a subsequent iteration is another two-dimensional floor plan for another floor adjacent the single floor and inside the building or the house, and wherein the arbitrary iteration and the subsequent iteration are two sequential iterations from the plurality of iterations for steps (B) through (H); and
transitioning from step (H) of the arbitrary iteration to step (B) of the subsequent iteration, if a user presence is detected by the pressure sensor of at least one specific LED cabinet during step (H) of the arbitrary iteration, and if the specific LED cabinet is displaying an entrance/exit during step (H) of the arbitrary iteration, wherein the specific LED cabinet is from the plurality of LED cabinets, and wherein the adjacent floor is accessible from the single floor through the entrance/exit.
